(19) United States
(12) Patent Application Publication
(10) Pub. No.: US 2004/0063289 A1
(43) Pub. Date: Apr. 1, 2004

(54) Reduction in source-drain resistance of semiconductor device

(75) Inventor: Hiroyuki Ohta, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 10/668,211

(22) Filed: Sep. 24, 2003

(30) Foreign Application Priority Data
Sep. 30, 2002 (JP) 2002-285372

(51) Int. Cl. H01L 21/336; H01L 21/3205; H01L 21/4763

(52) U.S. Cl. 438/303; 438/592

(57) ABSTRACT

A semiconductor device manufacture method has the steps of: (a) forming a gate electrode traversing a corresponding one of active regions and forming extension regions of source/drain in the active region on both sides of the gate electrode; (b) depositing first and second insulating films having different etching characteristics and anisotropically etching the first and second insulating films to form a side wall spacer on the side walls of the gate electrode; (c) selectively etching the first insulating film to form a retraction portion; (d) implanting ions to form source/drain regions in the silicon substrate; and (e) depositing metal capable of silicidation, and performing a silicidation reaction and form silicide regions also under the retraction portion.

### CROSS REFERENCE TO RELATED APPLICATION

This application is based on and claims priority of Japanese Patent Application No. 2002-285372 filed on Sep. 30, 2002, the entire contents of which are incorporated herein by reference.

### BACKGROUND OF THE INVENTION

A) Field of the Invention

The present invention relates to a semiconductor device and its manufacture method, and more particularly to a semiconductor device having micro MOS transistors and its manufacture method.

B) Description of the Related Art

MOS transistors in a large scale integrated (LSI) circuit are becoming finer and finer. A general MOS transistor has side wall spacers on the side walls of a gate electrode, source/drain extension regions under the side wall spacers, and high impurity concentration source/drain regions outside of the extension regions. A side wall spacer is generally required to be thicker than a certain value.

The gate length is shortened as well as the junction depth of source/drain regions is made shallow. In order to reduce the current which flows while the transistor is off, pocket regions of a conductivity type opposite to that of the extension region are formed under, or surrounding the extension regions of source/drain.

As micro fabrication progresses, the source-drain resistance becomes relatively high so that there is the tendency that drain current is hard to be flowed. In order to increase drain current, it is desired to reduce the source-drain resistance. The source-drain resistance can be reduced by forming silicide regions on the source/drain regions because the resistance of silicide is lower than that of silicon.

The silicide region is, however, a possible factor responsible for junction leak current. For example, Co suicide forms spikes depending upon its fabrication method and may form leak current sources distributed in a dot pattern.

As micro fabrication of MOS transistors advances, improvement on the characteristics of MOS transistors is restricted, posing a new issue.

### SUMMARY OF THE INVENTION

An object of this invention is to provide a semiconductor device having a novel structure capable of improving the characteristics of MOS transistors, and its manufacture method.

Another object of the invention is to provide a semiconductor device and its manufacture method capable of increasing drain current and suppressing an increase in leak current.

Still another object of the invention is to provide a semiconductor device and its manufacture method capable of improving the characteristics of MOS transistors without increasing the number of masks.

According to one aspect of the present invention, there is provided a semiconductor device manufacture method comprising the steps of: (a) forming a gate electrode on each of a plurality of active regions defined in a silicon substrate, the gate electrode traversing a corresponding one of the active regions, and forming extension regions of source/drain in the active region on both sides of the gate electrode; (b) depositing first and second insulating films having different etching characteristics over the silicon substrate, the first and second insulating films covering side walls of the gate electrode, and anisotropically etching the first and second insulating films to form side wall spacers on the side walls of each gate electrode; (c) selectively etching the first insulating film of the side wall spacers to form a retraction portion retracted from a surface of the second insulating film on a gate electrode side and on a silicon substrate side; (d) implanting ions into the silicon substrate by using the side wall spacers as a mask to form source/drain regions in the silicon substrate; and (e) depositing metal capable of silicidation over the silicon substrate to perform a silicidation reaction and form silicide regions.

According to another aspect of the invention, there is provided a semiconductor device comprising: a silicon substrate having a plurality of active regions; an insulated gate electrode formed on the silicon substrate and traversing a corresponding one of the active regions; side wall spacers formed on side walls of the insulated gate electrode and made of a lamination of first and second insulating films having different etching characteristics, the side wall spacer having retraction portions at the end face of the first insulating film retracted from a surface of the second insulating film; and a silicide region formed on a surface of the silicon substrate under the retraction portion and a thicker silicide region formed on the surface of the silicon substrate in an outer area of the silicide region.

As above, the source/drain resistance of a MOS transistor can be lowered.

Oblique ion implantation into an n-channel MOS transistor region can facilitate to balance the characteristics between n- and p-channel MOS transistors.

### BRIEF DESCRIPTION OF THE DRAWINGS

FIGS. 1A to 1X are cross sectional views, a photograph and a graph showing transistor characteristics, illustrating a semiconductor manufacture method according to a first embodiment of the invention.

FIGS. 2A to 2H are cross sectional views illustrating a semiconductor manufacture method according to a second embodiment of the invention.

FIGS. 3A to 3C are a schematic cross sectional view illustrating the feature of a transistor according to an embodiment and graphs showing simulation results.

FIG. 4 is a cross sectional view of a semiconductor integrated circuit device.

### DESCRIPTION OF THE PREFERRED EMBODIMENTS

Description will be made on the preferred embodiments of the invention, referring to the drawings.

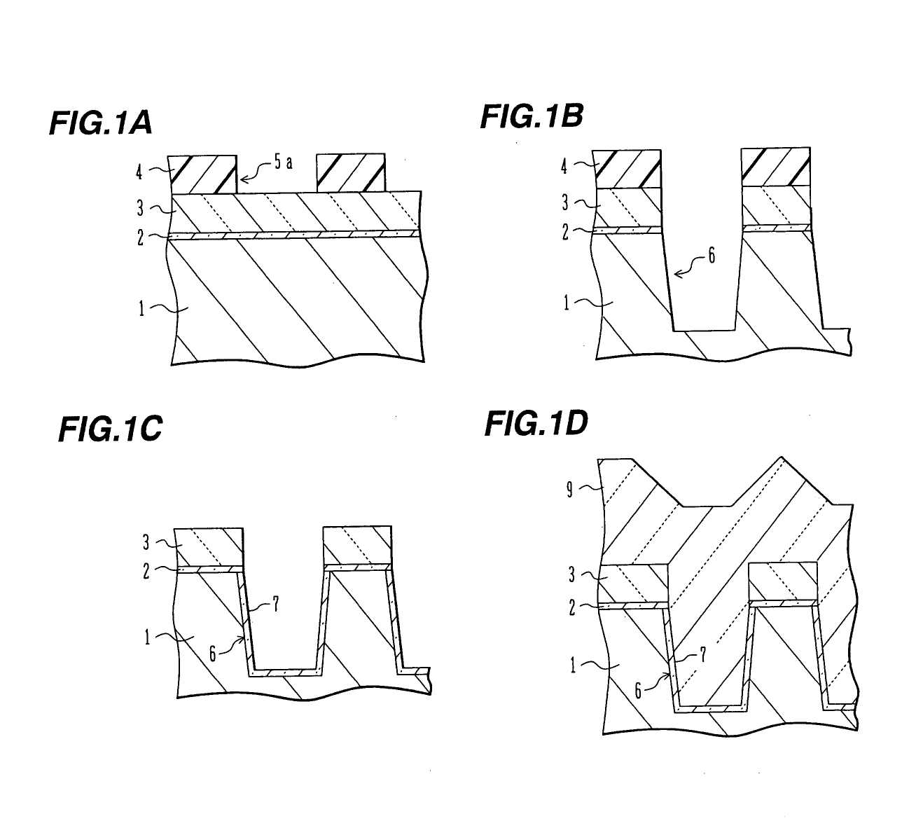

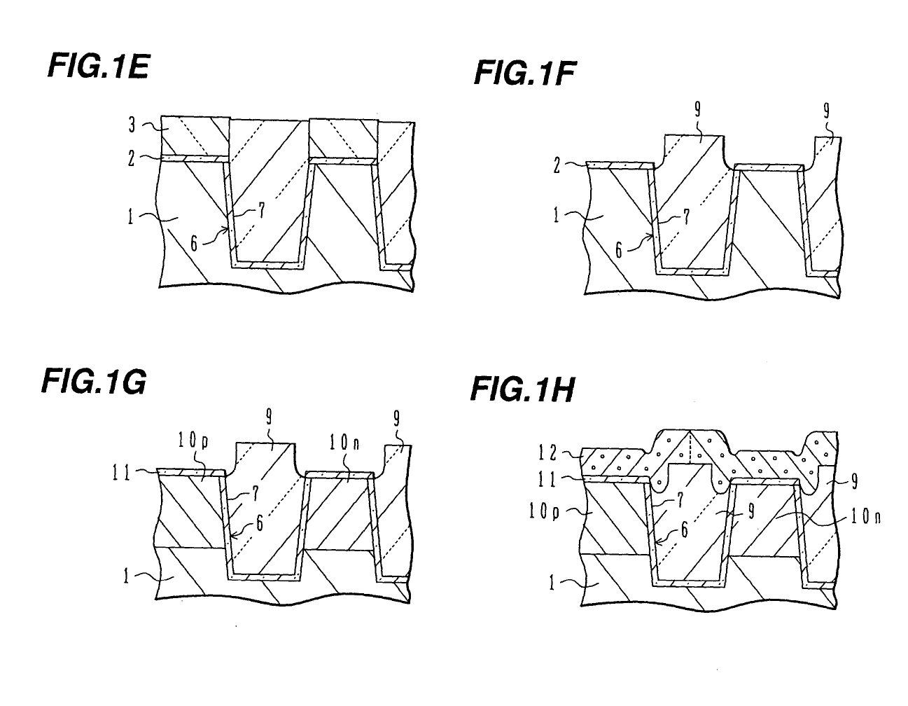

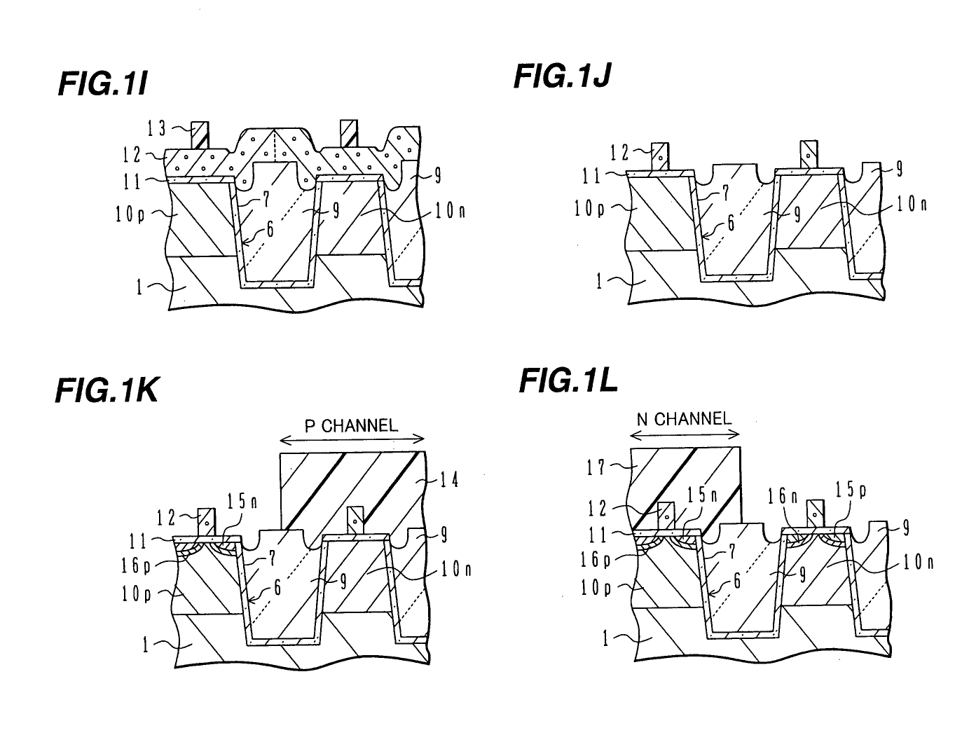

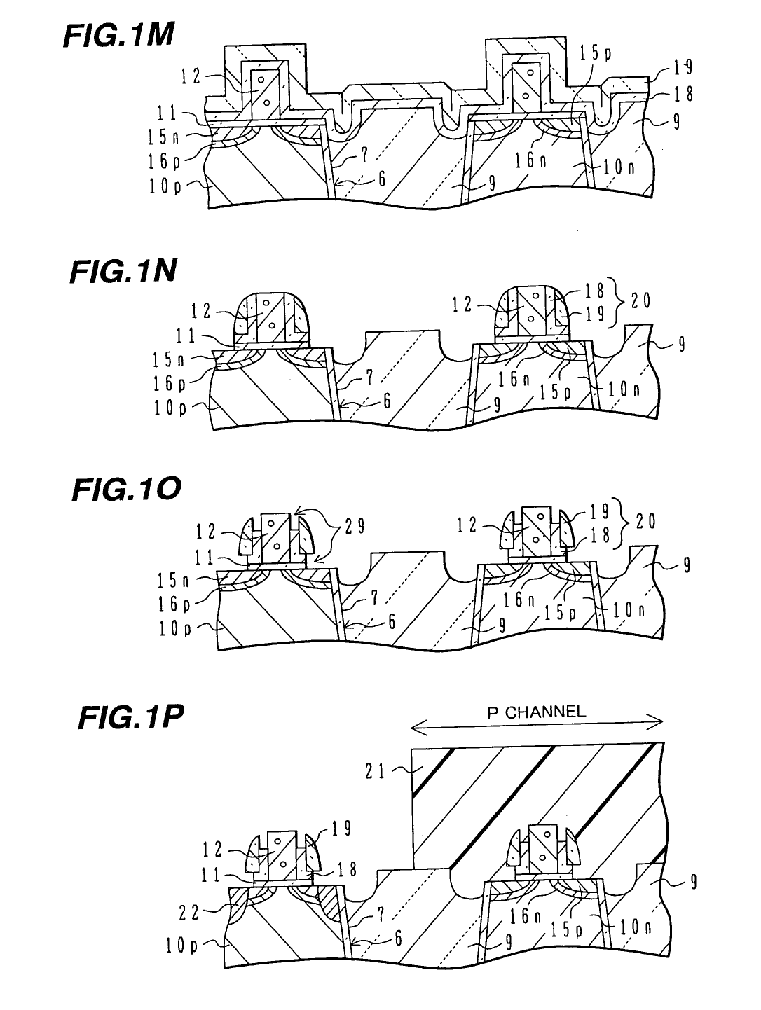

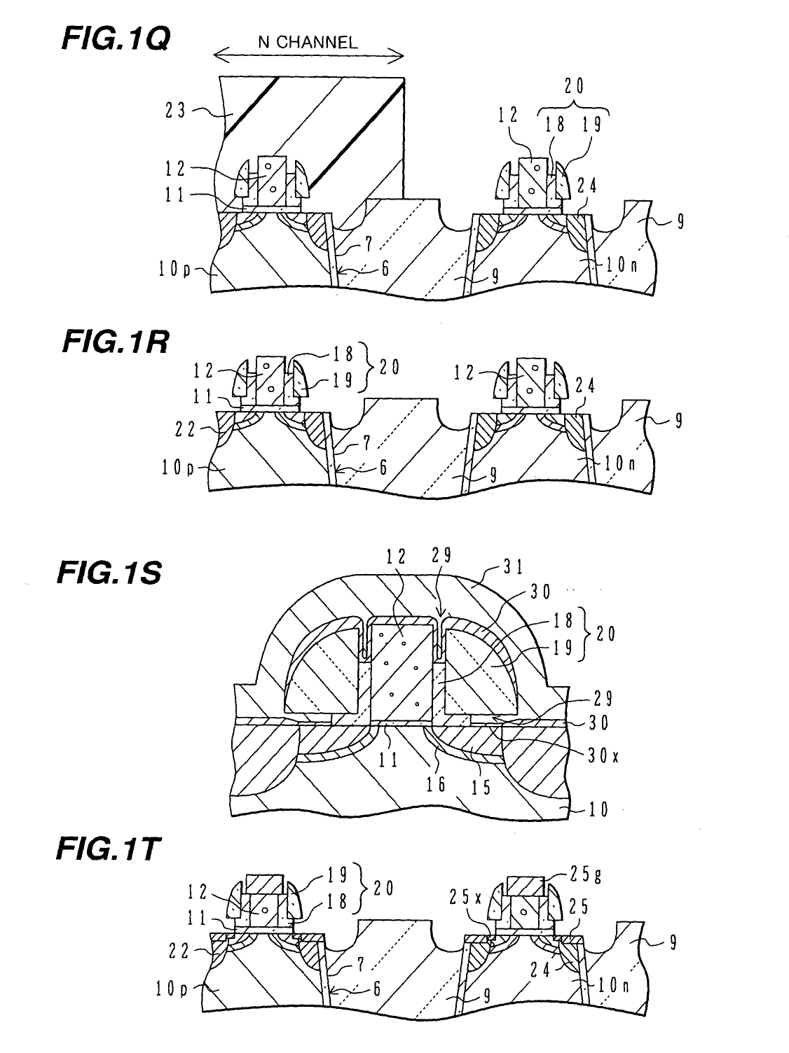

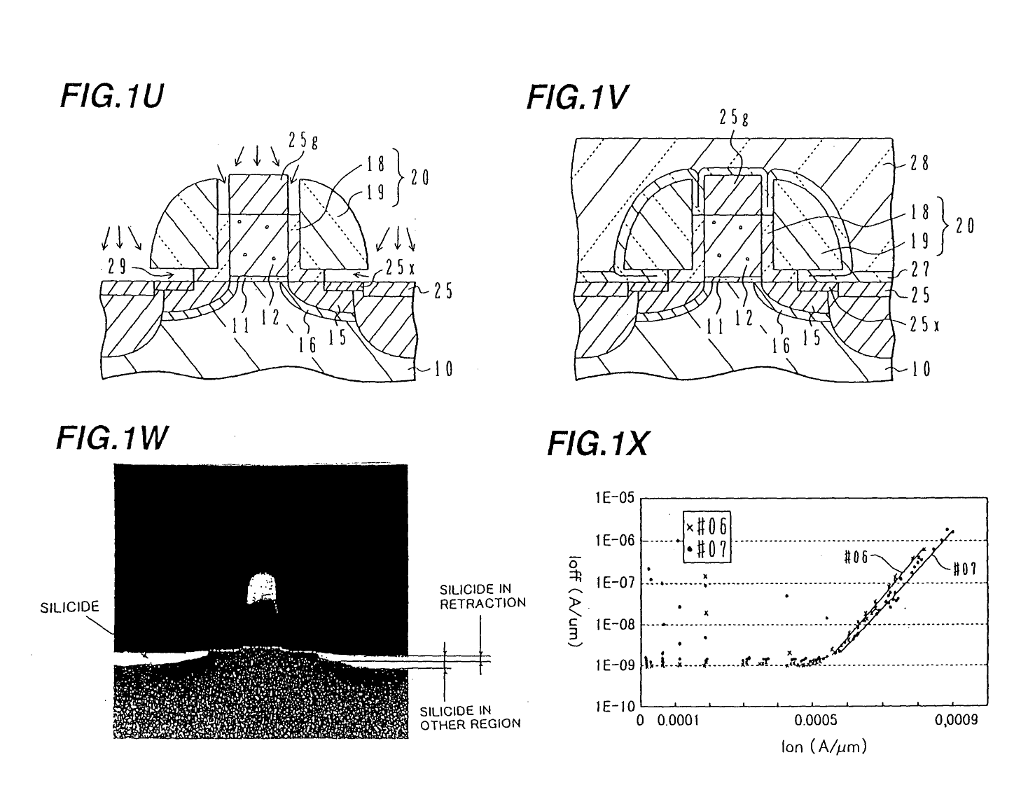

FIGS. 1A to 1W illustrate a semiconductor device manufacture method according to a first embodiment of the invention.

As shown in FIG. 1A, on the surface of a silicon substrate 1 of, for example, a p-type, a buffer silicon oxide film 2 is formed by thermal oxidation to a thickness of, for example, 10 nm. On this buffer silicon oxide film 2, a silicon nitride film 3 is deposited by chemical vapor deposition (CVD) to a thickness of, for example, 100 to 150 nm. A photoresist layer is coated on the silicon nitride film 3, exposed and developed to form a resist pattern 4 for the formation of an element isolation region. The resist pattern 4 has an opening 5a in an area corresponding to the element isolation region.

As shown in FIG. 1B, by using the resist pattern 4 as a mask, the silicon nitride film 3 and silicon oxide film 2 are etched and further the silicon substrate 1 is etched to form a trench 6 having a depth of, for example, 500 nm. The patterned silicon nitride film 3 can serve as a mask in the etching of the silicon substrate 1. The silicon nitride film and silicon oxide film are etched by using mixture gas of CH₄, CHF₃ and Ar as etching gas. The silicon substrate is etched by using mixture gas of HBr and O₂ as etching gas. The resist pattern 4 is thereafter removed.

As shown in FIG. 1C, on the surface of the silicon substrate 1 exposed in the trench 6, a silicon oxide film 7 is formed by thermal oxidation to a thickness of, for example, 10 nm.

As shown in FIG. 1D, a silicon oxide film 9 is deposited, for example, by high density plasma (HDP) CVD to a thickness of 500 nm, so as to bury the trench 6 formed with the silicon oxide film 7. The silicon oxide film 9 has an irregular surface in conformity with the underlying irregular surface.

As shown in FIG. 1E, the silicon oxide film 9 is polished by chemical mechanical polishing (CMP) to form a planarized surface. CMP is stopped when the surface of the silicon nitride film 3 is exposed. Annealing is thereafter performed in a nitrogen (N₂) atmosphere at 1000° C. to make dense the buried silicon oxide film 9.

As shown in FIG. 1F, the silicon nitride film 3 used as the mask for forming the trench and as a stopper for the CMP is removed by wet etching with hot phosphoric acid.

As shown in FIG. 1G, by using resist patterns, p-type ion implantation and n-type ion implantation are preformed to form a p-type well 1 Op and an n-type well 10n in the active regions.

The silicon oxide film on the upper surface of the silicon substrate is removed and thereafter a new silicon oxide film 11 as a gate insulating film is formed by thermal oxidation to a thickness of, for example, 2 nm.

As shown in FIG. 1H, on the gate insulating film 11, a polysilicon film 12 is formed by a low pressure (LP) CVD at a temperature of, for example, about 600° C. to a thickness of, for example, 100 nm. The polysilicon film 12 may be either a non-doped polysilicon film or a polysilicon film doped with impurities. If a polysilicon film doped with impurities is used, phosphorous (P) is doped in the region where n-channel MOS transistors are to be formed, whereas boron (B) are doped in the region where p-channel MOS transistors are to be formed.

As shown in FIG. 11, photoresist is coated on the polysilicon layer 12, and exposed and developed to form resist patterns 13. The resist patterns 13 each have a shape matching the shape of a gate electrode. By using the resist patterns as a mask, the polysilicon layer 12 is etched. After the polysilicon layer 12 is patterned into a gate electrode shape by anisotropical etching, the resist patterns 13 are removed.

FIG. 1J shows the shapes of the formed gate electrodes 12.

As shown in FIG. 1K, photoresist is coated over the surface of the silicon substrate, and exposed and developed to form a resist pattern 14 covering the p-channel MOS transistor region. Pocket regions 16p are formed by implanting p-type impurity ions, e.g., B ions into the exposed n-channel MOS transistor region. Extension regions 15n of source/drain are formed by implanting n-type impurity ions at an impurity concentration higher than that of the pocket regions. The order of ion implantation for the extension and pocket regions is optional. These processes form the extension regions of an n-channel MOS transistor and the pocket regions surrounding the extension regions. The resist pattern 14 is thereafter removed.

As shown in FIG. 1L, a resist pattern 17 is formed covering the n-channel MOS transistor region. Extension regions 15p and pocket regions 16n are formed by implanting p- and n-type impurity ions into the exposed p-channel MOS transistor region. The resist pattern 17 is thereafter removed. The processes shown in FIGS. 1A to 1L are known processes. Other known processes may be used to form a similar structure.

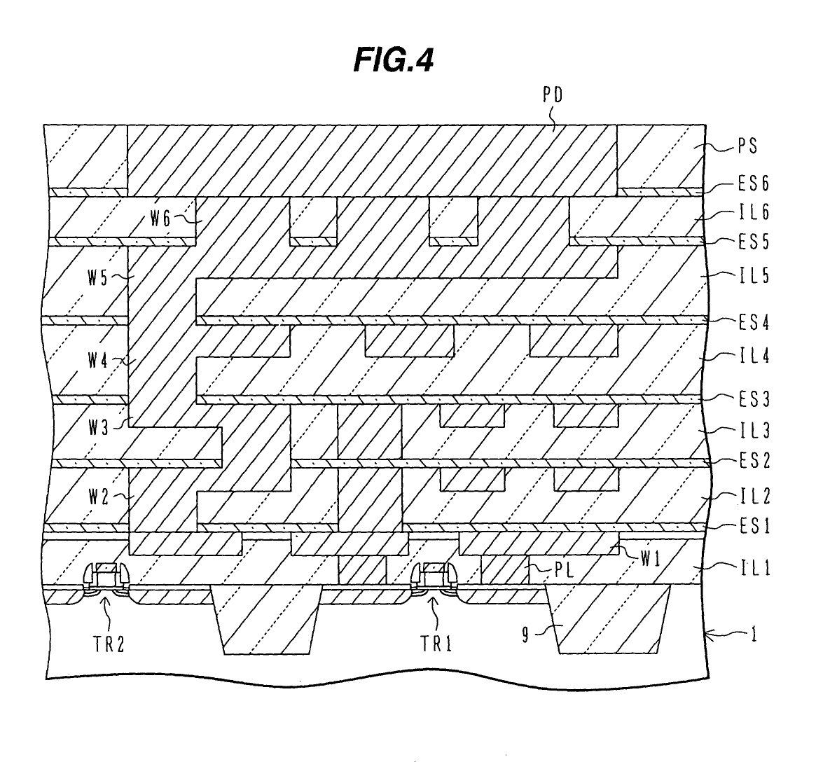

As shown in FIG. 4M, a silicon oxide film 18 having a thickness of, for example, 10 nm is deposited over the surface of the silicon substrate by low pressure (LP) CVD through reaction of tetraethoxysilane (TEOS) and O₂ source gases at a substrate temperature of 600° C. On the deposited silicon oxide film 18, a silicon nitride film 19 having a thickness of, for example, 90 nm is deposited by LPCVD through reaction of SiCl₂H₂ and NH₃ source gases at a substrate temperature of about 600° C.

Silane (SiH₄), bis-tertial-butylaminosilane (BTBAS) or the like may be used as the source gas of Si, instead of dichlorasilane (SiCl₂H₂). The thicknesses of the first layer silicon oxide film 18 and second layer silicon nitride film 19 are not limited to those described above. For example, the silicon oxide film 18 having a thickness of about 20 nm may be deposited and on this film the silicon nitride film 19 having a thickness of 80 nm may be deposited.

As shown in FIG. 1N, the laminated insulating films are dry-etched by reactive ion etching (RIE) to leave the laminated insulating films only on the side walls of the gate electrode 12. Side wall spacers 20 having a thickness of 100 nm are therefore formed on the side walls of the gate electrode 12. The side wall spacer 20 is made of laminated insulating films having different etching characteristics, the silicon oxide film 18 and silicon nitride film 19 in the above example.

As shown in FIG. 10, wet etching is performed to etch the lower insulation film of the laminated insulating films of side wall spacer 20. For example, side etching of 30 nm is performed in about 175 seconds by using dilute hydrofluoric acid aqueous solution of HF: H₂O=1:200. A side etch amount can be controlled by the etching time. For example, side etching of about 20 nm is performed in 110 seconds.

This etching process etches not only the silicon oxide film 18 exposed on the side surface of the side wall spacer 20 but also the silicon oxide film 18 exposed on the upper surface of the side wall spacer 20. The side wall spacer has therefore retraction portions 29 at the lower side surface and at the upper surface. In order to form an effective retraction portion, it is preferable to etch the silicon oxide film 18 at least 10 nm. If excessive side etching is performed, the function of the side wall spacer itself may be damaged. It is therefore preferable that the side etching is performed at most 0.6 times, and preferably at most about 0.4 times the thickness of the side wall spacer. The width of the side wall spacer 20 is set preferably to 30 nm or wider.

As shown in FIG. 1P, a resist pattern 21 is formed covering the p-channel MOS transistor region, and n-type impurity ions such as phosphorous (P) and arsenic (As) are implanted into the exposed n-channel MOS transistor region to form n-type diffusion regions 22. Oblique ion implantation inclined, for example, by 30 degrees from the substrate normal may be performed to position the source/drain regions 22 nearer to the gate electrode than the side wall spacers. The resist pattern 21 is thereafter removed.

As shown in FIG. 1Q, a resist pattern 23 is formed covering the n-channel MOS transistor region to expose the p-channel MOS transistor region.

Boron (B) or boron fluoride (BF₂) ions are implanted as p-type impurity ions to form p-type source/drain regions 24. B as the p-type impurity has a quality easier to diffuse than P or As as the n-type impurity. Although n-type impurity ions are obliquely implanted, p-type impurity ions B are vertically implanted. The resist pattern 23 is thereafter removed.

As shown in FIG. 1R, impurities in the impurity doped regions are activated by annealing, for example, at 1000° C. for 10 seconds.

As shown in FIG. 1S, metal capable of silicidation such as cobalt (Co) is deposited over the substrate formed with the impurity doped regions. For example, a Co film 30 having a thickness of about 5 nm is formed by sputtering by using a Co target and applying a DC bias of about 250 W. In this case, a thin Co film 30x is deposited in the retraction portion 29 because of Co scattering and the like. Next, a TiN film having a thickness of about 30 nm is deposited by using a TiN target and applying a DC bias of about 9000 W.

As shown in FIG. 1T, a primary silicidation reaction of Co is performed by low temperature annealing in a nitrogen atmosphere, for example, at about 500° C. for 30 seconds. Next, the TiN layer and unreacted metal capable of silicidation, e.g. Co, is removed, for example, by mixture liquid of ammonium peroxide and persulfuric acid. A secondary silicidation reaction is performed by high temperature annealing, for example, at about 700° C. for about 30 seconds in a nitrogen atmosphere. In this manner, low resistance silicide layers 25 are formed. Nickel silicide may be used in place of cobalt silicide. Silicide regions 25 and 25g are therefore formed on the exposed surface of the silicon substrate 1 and on the exposed polysilicon layer of the gate electrode 12.

FIG. 1U shows the details of the silicidation process. The side wall spacer 20 is made of a lamination of the lower layer silicon oxide film 18 and upper layer silicon nitride film 19. The lower layer silicon oxide film 18 has the side-etched retraction portion 29. With Co sputtering on such a gate structure, Co flying along an oblique direction enters also the inside of the side retraction portion 29 formed in the side wall spacer 20. Co scattered by the substrate surface may also enter the side retraction portion 29. The Co film 30x is therefore deposited also in the retraction portion.

The amount of cobalt deposited in the inside of the retraction portion 29 is smaller than that of Co deposited on the exposed surface of silicon or polysilicon. With annealing to follow, the silicidation reaction occurs so that the silicide region 25 is formed. The silicide region 25x is also formed by cobalt deposited on the bottom surface of the side retraction portion. This silicide region 25x lowers the resistance of the extension region 15. The top retraction also receives Co sputtering and causes silicidation of polysilicon gate electrode.

The amount of metal capable of being silicidated and entered the side retraction portion changes with the thickness of the first insulating film 18. If the thickness of the silicon oxide film 18 is about 20 nm, a considerable amount of cobalt enters the retraction portion and a corresponding silicide region 25x is formed. If the silicon oxide film 18 is thinned, the amount of entering cobalt reduces. Almost similar characteristics can be realized by using nickel instead of cobalt.

As shown in FIG. 1V, an insulating film 27 made of, for example, silicon nitride is deposited on the substrate surface by CVD. The silicon nitride film 27 readily enters the retraction portion and buries the retraction portion. An insulating film 28 of silicon oxide or the like is deposited over the substrate surface. The insulating film 28 buries the gate electrode and constitutes an interlayer insulating film. Known various structures may be adopted as the interlayer insulating film.

FIG. 1W is an scanning electron microscopy (SEM) photograph showing the cross sectional view of a sample transistor formed by the manufacture method of the above-described embodiment. The lower layer insulating film of the side wall spacer was made of a silicon oxide layer having a thickness of about 20 nm, and the upper layer silicon oxide film was made of a silicon nitride film having a thickness of about 80 nm. The silicide regions on the substrate surface include a thin silicide region under the retraction portion and a thick silicide region outside of the side wall spacer.

This thin silicide region under the retraction region lowers the resistance of the extension region and prevents an increase in leak current. The thick silicide region outside of the side wall spacer lowers efficiently the resistance of the source/drain region.

The gate electrode is subjected to the silicide reaction not only on the upper surface but also on the upper side surfaces to form a thick silicide region. This thick silicide region lowers efficiently the resistance of the gate electrode.

FIG. 1X is a graph showing the characteristics of the sample shown in FIG. 1W. For the purposes of comparison, a sample without retraction portions was formed and the characteristics thereof were measured. In FIG. 1X, the abscissa represents a drain on-current Ion and the ordinate represents a drain off-current Ioff.

A curve #06 indicates the characteristics of the sample without retraction portions, and a curve #07 indicates the characteristics of the sample with the retraction portions. As seen from the graph, the on-current Ion of the embodiment sample at the same off-current Ioff is improved, i.e., the drain current increases.

According to the first embodiment, the side wall spacer is made of a lamination of insulating layers having different etching characteristics, and the lower insulating layer is side-etched to expose the substrate surface in the retraction portion entered in the side wall spacer. As a cobalt film is deposited by sputtering, a thin cobalt film is formed also on the substrate surface in the retraction portion. As the cobalt film is silicidated, a thick silicide layer is formed outside of the side wall spacer, and a thin silicide layer is formed under the retraction portion.

This silicide layer lowers the resistant of the extension regions of source/drain. Since the silicide layer on the extension region is thin, an increase in leak current can be suppressed.

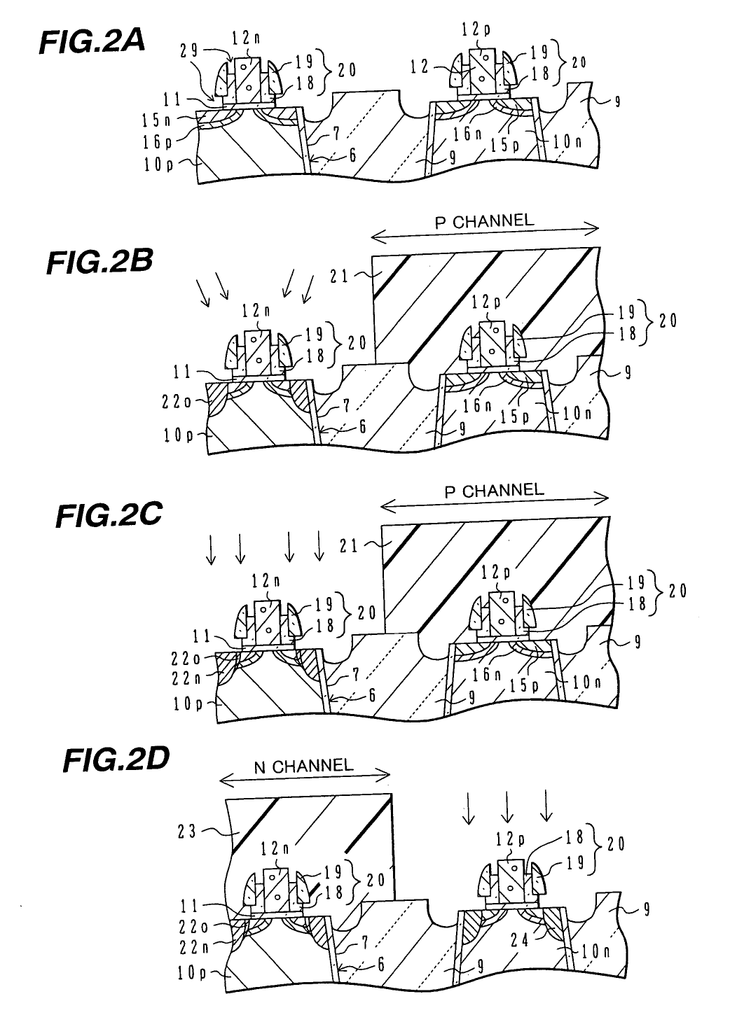

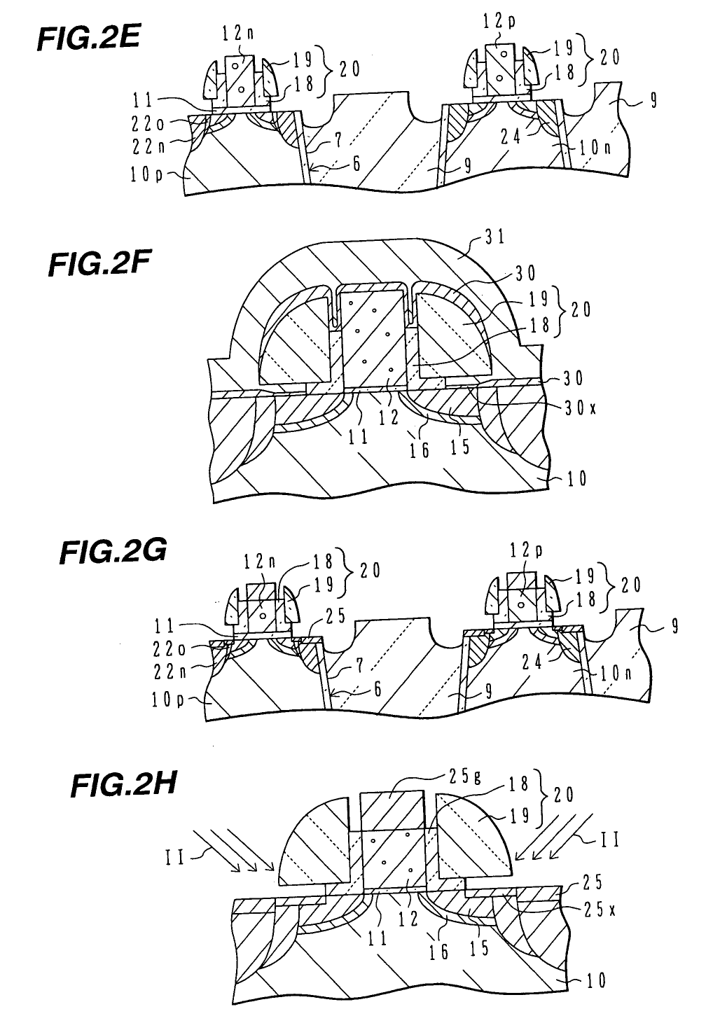

FIGS. 2A to 2H are cross sectional views illustrating a semiconductor device manufacture method according to a second embodiment of the invention.

FIG. 2A shows the structure of a semiconductor substrate underwent the processes shown in FIGS. 1A to 1N. This structure is the same as that shown in FIG. 1O. On the side walls of the gate electrodes 12n and 12p, side wall spacers 20 are formed which are each made of a lamination of the silicon oxide layer 18 and silicon nitride layer 19. The first layer silicon oxide layer 18 was side-etched by about 30 nm. While side etching progresses from the side surface of the side wall spacer, etching also progresses from the side wall spacer upper surface. Retraction portions 29 are therefore formed on the side surface and upper surface of the side wall spacer.

As shown in FIG. 2B, the p-channel MOS transistor region is covered with the resist pattern 21. Oblique ion implantation is performed by implanting n-type impurities such as phosphorous (P) and arsenic (As) into the n-channel MOS transistor region along the direction slanted by 30 degrees from the substrate normal. For example, oblique ion implantation is performed along four directions symmetrical in a substrate plane. Since the first layer 18 of the side wall spacer 20 was side-etched, n-type impurity ions are obliquely implanted efficiently under the retraction portion. Therefore, a distance between high impurity concentration regions 22o becomes short.

As shown in FIG. 2C, by using the same resist pattern as a mask, n-type impurity ions such as phosphorous (P) and arsenic (As) are implanted along the substrate normal direction. A much higher impurity concentration region 22n is therefore formed sideways from the side wall spacer 20. Both the oblique ion implantation and the vertical ion implantation are performed to lower the source/drain resistances, compared to the oblique ion implantation for forming the source/drain regions in the first embodiment. The resist pattern 21 is thereafter removed.

As shown in FIG. 2D, a resist pattern 23 is formed covering the n-channel MOS transistor region. Source/drain regions 24 are formed by implanting p-type impurity ions such as boron (B) and boron fluoride (BF₂) into the p-channel MOS transistor region along the substrate normal direction. The resist pattern 23 is thereafter removed.

As shown in FIG. 2E, the semiconductor substrate subjected to ion implantation undergoes activation annealing, for example, at 1000° C. for 10 seconds, to electrically activate implanted impurity ions.

As shown in FIG. 2F, a cobalt layer 30 is formed over the substrate surface by sputtering using a cobalt target. Sputtered cobalt enters the retraction portion retracted from the side surface of the side wall spacer so that a thin cobalt layer 30 is also formed. The cobalt layer deposited has a thickness of about 5 nm on the flat surface. Next, a TiN layer 31 is deposited to a thickness of, for example, 30 nm by sputtering.

As shown in FIG. 2G, after sputtering, a primary silicidation reaction of the deposited cobalt layer is performed through annealing, for example, at about 500° C. for about 30 seconds in a nitrogen atmosphere. Next, the TiN layer and unreacted cobalt layer are removed, for example, by mixture liquid of ammonium peroxide and persulfuric acid. Thereafter, a secondary silicidation reaction is performed by annealing, for example, at about 700° C. for about 30 seconds in a nitrogen atmosphere. In this manner, low resistance silicide layers are formed. Nickel silicide may be used in place of cobalt silicide.

FIG. 2H shows the details of oblique ion implantation for the side wall spacer with the retraction portion. The lower silicon oxide layer 18 of the side wall spacer 20 has the side-etched retraction portion, for example, of about 20 nm. Obliquely implanted n-type impurity ions can invade into the retraction portion above the substrate surface without being intercepted by the insulating layer. The impurity doped regions can therefore be formed nearer to the gate electrode, corresponding to the height of the retraction portion.

Diffusion of n-type impurity P or As is of less order, compared to diffusion of p-type impurity B. If p- and n-channel MOS transistors are formed under the same conditions, the source-drain distance of an n-channel MOS transistor becomes longer than that of a p-channel MOS transistor. By performing oblique ion implantation for an n-channel MOS transistor, the source-drain distance of the n-channel MOS transistor can be shortened so that the characteristics of CMOS transistors can be balanced easily.

Succeeding silicidation reactions form the silicide region 25 outside of the side wall spacer and the shallow silicide region 25x under the retraction portion. The source-drain resistance can be lowered further, similar to the first embodiment.

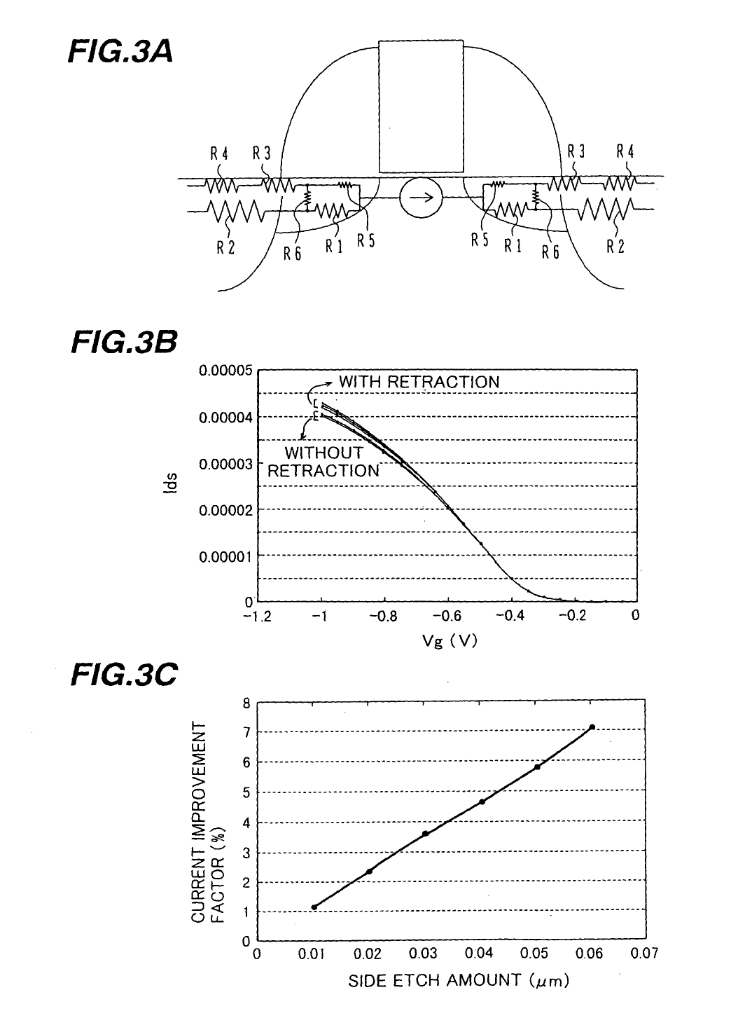

FIG. 3A is a schematic diagram showing the resistance distribution between source and drain regions with the silicide regions. As the extension region of source/drain and the high impurity concentration source/drain region are formed, their respective resistances R1 and R2 are serially connected.

As the silicide layer is formed in the silicon surface layer, a serial connection of resistances R3 and R4 is connected in parallel to a serial connection of resistances R1 and R2. Resistances R5 and R6 are distributed between the suicide region and the impurity doped region of the silicon substrate resistances network shown in FIG. 3A is therefore formed which can lower the resistance between the source and drain regions more than the resistance network consisted of only the resistances R1 and R2.

FIG. 3B is a graph showing a change in drain current relative to a change in gate voltage obtained through simulation. In FIG. 3B, the abscissa represents a gate voltage Vg and the ordinate represents a saturated drain current Ids. The simulation parameters include a gate length of 40 nm, a side wall spacer width of 100 nm, a diffusion layer depth of 21.75 nm, and a sheet resistance of 1.011 kΩ/□. This simulation confirmed that the retraction portion increases the saturate drain current Ids.

FIG. 3C is a graph showing simulation result of a current increase factor relative to a side etch amount of a first layer of the laminated side wall spacer. The abscissa represents a side etch amount in the unit of μm and the ordinate represents a current improvement factor in the unit of %. This simulation confirmed that as the side etch amount increases, the current improvement factor increases almost linearly.

FIG. 4 is a cross sectional view of an integrated circuit device including MOS transistors formed by the above-described embodiment. In the surface layer of a silicon substrate 1, a shallow trench isolation (STI) 9 is formed for isolating active regions. Transistors TR1 and TR2 are formed in the active regions defined by STI. These transistors were formed by the above-described embodiment method.

A first interlayer insulating film IL1 is formed burying the transistors. Conductive plugs PL and first wiring layers W1 are buried in the first interlayer insulating film IL1. An etch stopper layer ES1 such as a silicon nitride film is formed on the first wiring layer W1. A second interlayer insulating film IL2 is formed on the etch stopper layer ES1. A second wiring layer W2 of a damascene structure is formed through the second interlayer insulating film IL2 and etch stopper layer ES1.

Similarly, on the second interlayer insulating film IL2, a lamination is formed which includes an etch stopper layer ES2, an interlayer insulating film IL3, an etch stopper layer ES3, an interlayer insulating film IL4, an etch stopper layer ES4, an interlayer insulating film IL5, an etch stopper layer ES5, an interlayer insulating film IL6, an etch stopper layer ES6 and a passivation film PS, stacked in this order from the bottom. Wiring layers W3, W4, W5 and W6 are formed through corresponding layers of the lamination. Contact pads PD are formed through the passivation film.

A high performance semiconductor integrated circuit can be realized by lowering the source-drain resistance of each MOS transistor constituting the integrated circuit.

The present invention has been described in connection with the preferred embodiments. The invention is not limited only to the above embodiments. It will be apparent to those skilled in the art that various modifications, improvements, combinations, and the like can be made.

What we claim are:

1. A semiconductor device manufacture method comprising steps of:
(a) forming a gate electrode over each of a plurality of active regions defined in a silicon substrate, said gate electrode traversing a corresponding one of the active regions, and forming extension regions of source/drain in the active region on both sides of said gate electrode;
(b) depositing first and second insulating films having different etching characteristics on the silicon substrate, said first and second insulating films covering side walls of said gate electrode, and anisotropically etching said first and second insulating films to form a side wall spacer on the side walls of each gate electrode;
(c) selectively etching said first insulating film of the side wall spacer to form a retraction portion retracted from a surface of said second insulating film on a gate electrode side and on a silicon substrate side;
(d) implanting ions into the silicon substrate by using the side wall spacer as a mask to form source/drain regions in the silicon substrate; and
(e) depositing metal capable of silicidation over the silicon substrate and performing a silicidation reaction and form silicide regions.

2. The semiconductor device manufacture method according to claim 1, wherein selective etching at said step (c) is isotropical etching.

3. The semiconductor device manufacture method according to claim 2, wherein said first insulating film is made of silicon oxide, said second insulating film is made of silicon nitride, and said step (c) selectively wet-etches silicon oxide with dilute hydrofluoric acid aqueous solution.

4. The semiconductor device manufacture method according to claim 1, wherein said step (c) side-etches said first insulating film at least by 10 nm and at most 0.6 times a width of the side wall spacer.

5. The semiconductor device manufacture method according to claim 1, wherein the plurality of active regions include n- and p-channel regions, said step (d) includes a step of obliquely implanting n-type impurity ions into the n-channel region, while p-type impurity ions are implanted into the p-channel region only at an angle nearer to a substrate normal than the oblique ion implantation.

6. The semiconductor device manufacture method according to claim 5, wherein said step (d) includes a step of obliquely implanting n-type impurity ions into the n-channel region and a step of vertically implanting n-type impurity ions into the n-channel region.

7. A semiconductor device manufacture method according to claim 1, wherein said step (e) sputters Co or Ni on the silicon substrate and also in the retraction portion on the silicon substrate side, and forms the silicide region also on the silicon substrate under the retraction portion and a thicker silicide region on the silicon substrate outside of the side wall spacer.

8. The semiconductor device manufacture method according to claim 1, further comprising a step of:
(f) after said step (e), depositing a third insulating film on the silicon substrate, the third insulating film entering the retraction portion and burying the retraction portion.

9. A semiconductor device manufacture method comprising steps of:
(a) forming a gate electrode in each of a plurality of active regions defined in a silicon substrate, said gate electrode traversing the active region, and forming extension regions of source/drain in the active region on both sides of said gate electrode;
(b) depositing first and second insulating films having different etching characteristics on the silicon substrate, said first and second insulating films covering side walls of said gate electrode, and anisotropically etching said first and second insulating films to form a side wall spacer on the side walls of each gate electrode;
(c) selectively etching said first insulating film of the side wall spacer to form a retraction portion retracted from a surface of said second insulating film on a side surface and an upper surface of the side wall spacer;
(d) implanting ions into the silicon substrate by using the side wall spacer as a mask to form source/drain regions in the silicon substrate; and
(f) depositing a third insulating film on the silicon substrate, the third insulating film entering the retraction portion and burying the retraction portion.

10. The semiconductor device manufacture method according to claim 9, wherein the plurality of active regions include n- and p-channel regions, said step (d) includes a step of obliquely implanting n-type impurity ions into the n-channel region, and implanting p-type impurity ions into the p-channel region only at an angle nearer to a substrate normal than the oblique ion implantation.

11. The semiconductor device manufacture method according to claim 10, wherein said step (d) includes a step of obliquely implanting n-type impurity ions into the n-channel region and a step of vertically implanting n-type impurity ions into the n-channel region.

12. The semiconductor device manufacture method according to claim 9, further comprising a step of:
(e) after said step (d), depositing metal capable of silicidation over the silicon substrate by sputtering, and performing a silicidation reaction and form silicide regions.

13. The semiconductor device manufacture method according to claim 12, wherein the metal capable of silicidation is cobalt or nickel.

14. The semiconductor device manufacture method according to claim 10, further comprising a step of:
(e) after said step (d), depositing metal capable of silicidation over the silicon substrate by sputtering, and performing a silicidation reaction and form silicide regions.

15. The semiconductor device manufacture method according to claim 14, wherein the metal capable of silicidation is cobalt or nickel.

16. A semiconductor device comprising:
a silicon substrate having a plurality of active regions;
an insulated gate electrode formed on said silicon substrate and traversing a corresponding one of the active regions;
a side wall spacer formed on side walls of said insulated gate electrode and made of a lamination of first and second insulating films having different etching characteristics, said side wall spacer having retraction portions at the end face of the first insulating film retracted from a surface of the second insulating film; and
a silicide region formed on a surface of said silicon substrate under the retraction portion and a thicker silicide region formed on the surface of said silicon substrate in an outer area of said silicide region.

17. The semiconductor device according to claim 16, wherein said insulated gate electrode includes a polysilicon layer, and polysilicon which contacts the retraction portion in an upper region of the said side wall spacer is silicidated.

18. The semiconductor device according to claim 16, further comprising a third insulating film deposited on said silicon substrate and burying the retraction portion.

19. The semiconductor device according to claim 17, further comprising a third insulating film deposited on said silicon substrate and burying the retraction portion.
